(19) United States
(12) Patent Application Publication
(10) Pub. No.: US 2025/0183812 A1
(43) Pub. Date: Jun. 5, 2025

(54) BATTERY DEVICE FOR PROVIDING THREE-PHASE ALTERNATING CURRENT INDEPENDENTLY OF LOCATION

(71) Applicant: ECOVOLTA AG, Brunnen (CH)

(72) Inventors: Benjamin FRIEDRICH, Morschach (CH); Manuel RÄBER, Winterthur (CH); Pirmin REICHMUTH, Schwyz (CH); Vera TRUTMANN, Brunnen (CH)

(21) Appl. No.: 18/864,502

(22) PCT Filed: May 10, 2023
(86) PCT No.: PCT/EP2023/062521

§ 371 Date: Nov. 8, 2024

(30) Foreign Application Priority Data
May 10, 2022 (CH) CH000558/2022
Apr. 28, 2023 (CH) CH000463/2023

(51) Int. Cl. H02M 7/00; H01M 10/42; H01M 10/613; H01M 10/627; H01M 10/643; H01M 10/6551; H01M 50/251; H05K 5/02; H05K 7/20

(52) U.S. Cl. CPC H02M 7/003; H01M 10/425; H01M 10/613; H01M 10/627; H01M 10/643; H01M 10/6551; H01M 50/251; H05K 5/0217; H05K 7/209; H01M 2220/10

(57) ABSTRACT

A rechargeable battery device for providing three-phase alternating current independently of location is achieved. It comprises a housing providing for a three-phase alternating current output. One or more rechargeable battery packs, at least one bidirectional three-phase inverter as well as one or more common mode filters are accommodated in the housing. The housing incorporates one or more heatsinks with a heat-dissipating surface. The energy density of the rechargeable battery device corresponding to the gross capacity of the one or more rechargeable battery packs in relation to the residual weight of the rechargeable battery device is at least 0.1 kWh/kg, wherein the residual weight corresponds to a total weight of the rechargeable battery device minus a weight of the one or more rechargeable battery packs.

The invention relates to an accumulator/rechargeable battery device, ‘Akku-Vorrichtung’ for short, for providing three-phase alternating current independently of location, the device providing at least one connection for a three-phase load in the form of a three-phase alternating current output.

Transportable energy supply apparatuses with a connection for single-phase loads are known in the state of the art. The capacities of the rechargeable battery packs installed in such energy supply apparatuses are usually in a range between about 2-5 kWh. Accordingly, these apparatuses, although transportable, can only be used to a limited extent, as the capacities provided are not sufficient for power-intensive applications.

For many household and office applications, the standard grid voltage is perfectly adequate because single-phase loads can be used. However, this is not usually the case in trade or industry. Here, tools, motors, machines and systems require more power for the electrical energy supply, i.e. they rely on three-phase alternating current and are therefore referred to as three-phase loads, wherein the effective value of the voltage is then substantially higher. In professional applications, typically in the fields of construction, trade, industry, event technology, film technology, protection and rescue services, etc., loads drawing intensive electrical power are generally used, which must be operated with three-phase alternating current.

Power supply apparatuses for providing three-phase alternating current according to the state of the art are very heavy, which is why they cannot be moved by people alone. The loading and unloading of such energy supply apparatuses cannot be carried out manually. They are usually configured as stationary charging stations or they are stored in vehicles, typically in vans or trailers. A significant proportion of the weight of such heavy energy supply apparatuses is also accounted for by their coolers. Because rechargeable batteries with high capacities and power require a higher cooling capacity, such rechargeable battery devices are often water-cooled. Apart from the disadvantageous weight aspect, the susceptibility of the water cooling and the associated maintenance requirements are also high. Rechargeable batteries with high capacities and power outputs also have poorer electromagnetic compatibility (EMC) due to noise and interference signals.

Against this background, it is the object of the present invention to provide an easy to handle, i.e. lightweight, rechargeable battery device for providing three-phase alternating current independently of location, which can then be usefully utilized for three-phase loads drawing intensive power. In particular, this is intended to open up the professional field of application for mobile rechargeable battery devices.

This object is achieved by a rechargeable battery device according to the features of independent claim 1. Further advantageous variants of this rechargeable battery device and its use are specified in the dependent claims.

The rechargeable battery device according to the invention is described with reference to exemplary embodiments in the following figures. In the drawings:

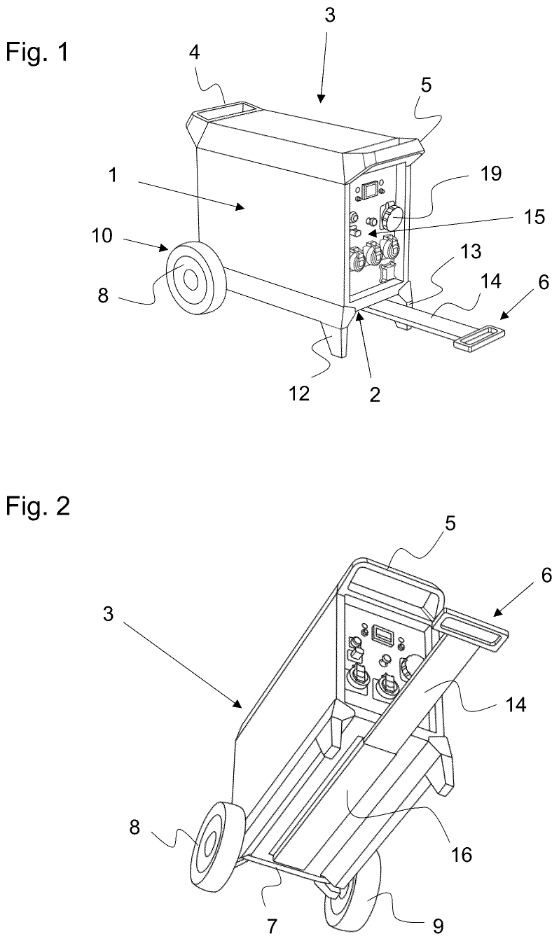

FIG. 1 shows the mobile rechargeable battery device with extended lifting handle;

FIG. 2 shows a perspective view of the mobile rechargeable battery device according to FIG. 1, seen from below;

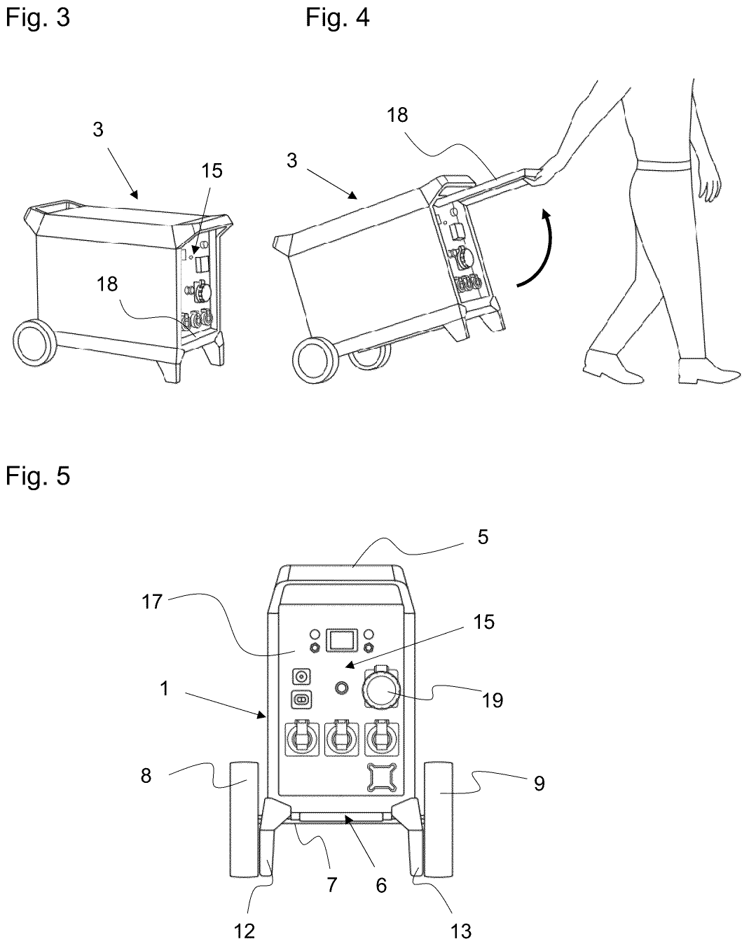

FIG. 3 shows the mobile rechargeable battery device with a fold-out lifting handle, with the lifting handle folded in;

FIG. 4 shows the mobile rechargeable battery device according to FIG. 3 with the lifting handle folded out when being pulled by a person;

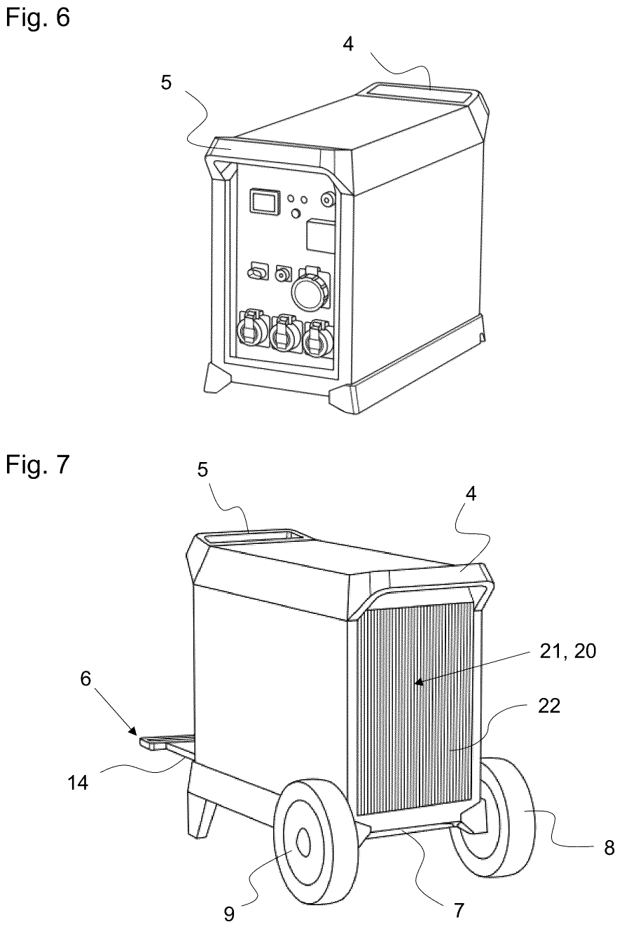

FIG. 5 shows the mobile rechargeable battery device in a view of the end face of the housing with the outputs for connecting electrical loads; shows the mobile rechargeable battery device without wheels in a FIG. 6 perspective view of the end face with the outputs for connecting electrical loads;

FIG. 7 shows the mobile rechargeable battery device with wheels in a perspective view of the side with the wheels and the cooling surface;

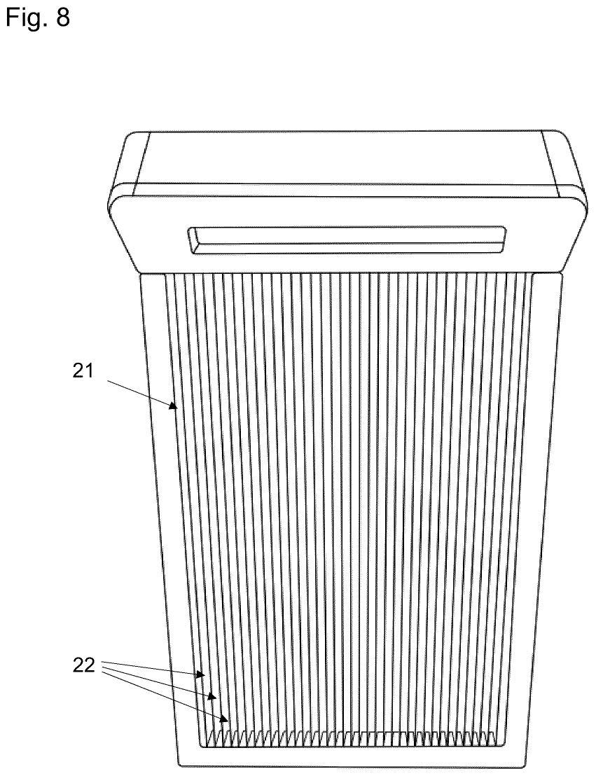

FIG. 8 shows the mobile rechargeable battery device without wheels, looking at the side with the heatsink, with the cooling fins protruding inwards;

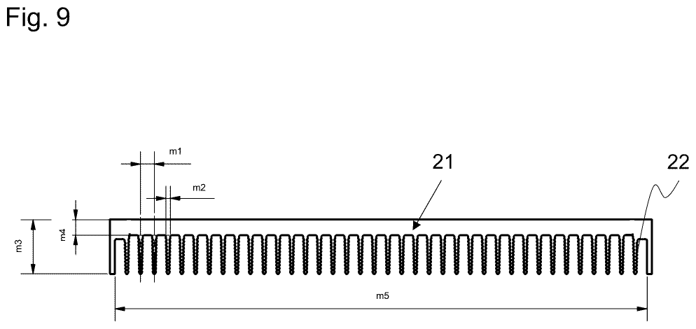

FIG. 9 shows a cross-section of the heatsink of the rechargeable battery device with its plurality of structured cooling fins;

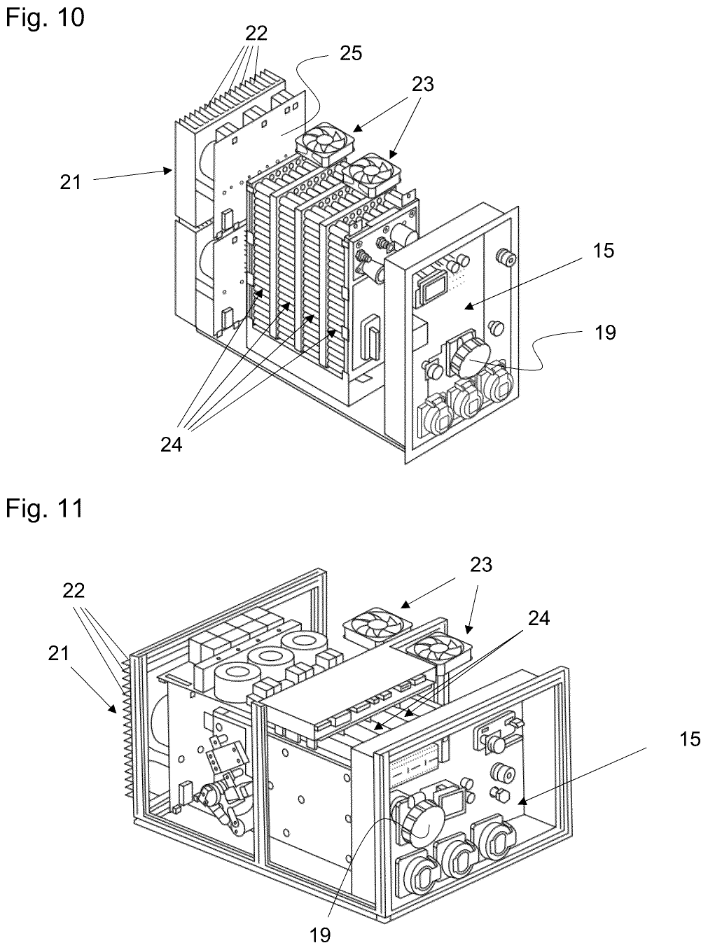

FIG. 10 shows the internal structure of the mobile rechargeable battery device with heatsink;

FIG. 11 shows the internal structure of another embodiment of the mobile rechargeable battery device with heatsink;

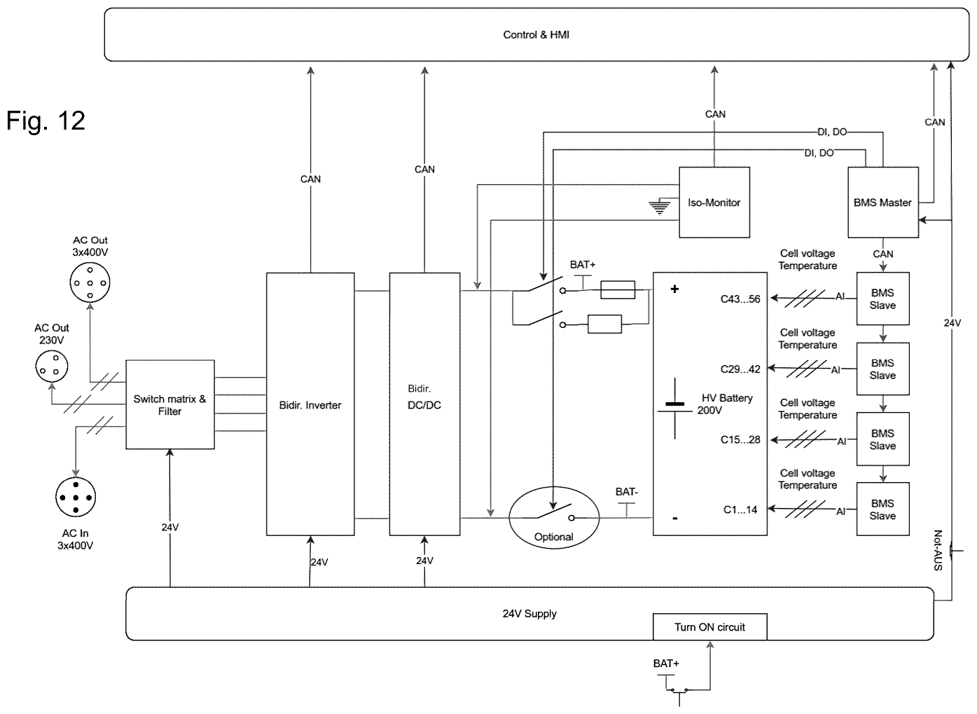

FIG. 12 shows a circuit diagram explaining the power electronics installed in the mobile rechargeable battery device;

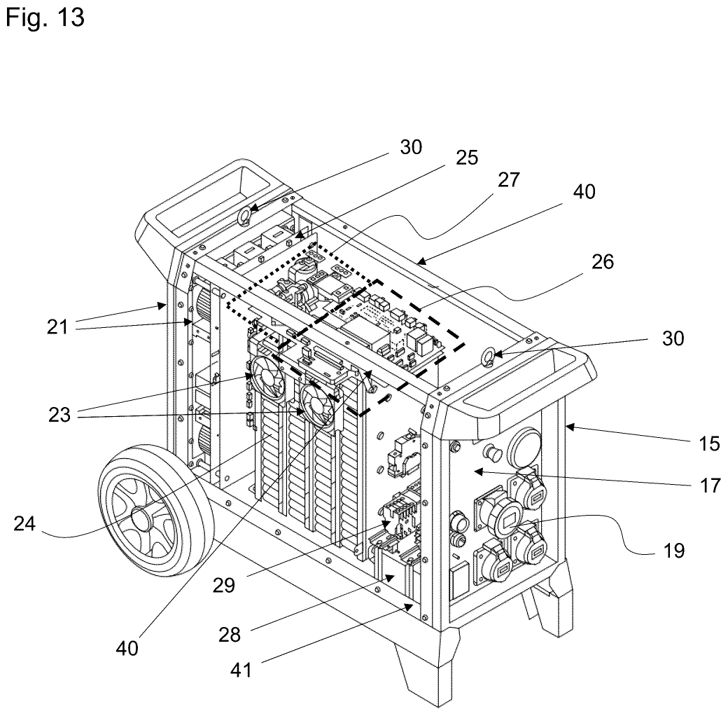

FIG. 13 shows the mobile rechargeable battery device in a perspective view without the top plate and side walls of its housing to reveal its internal components;

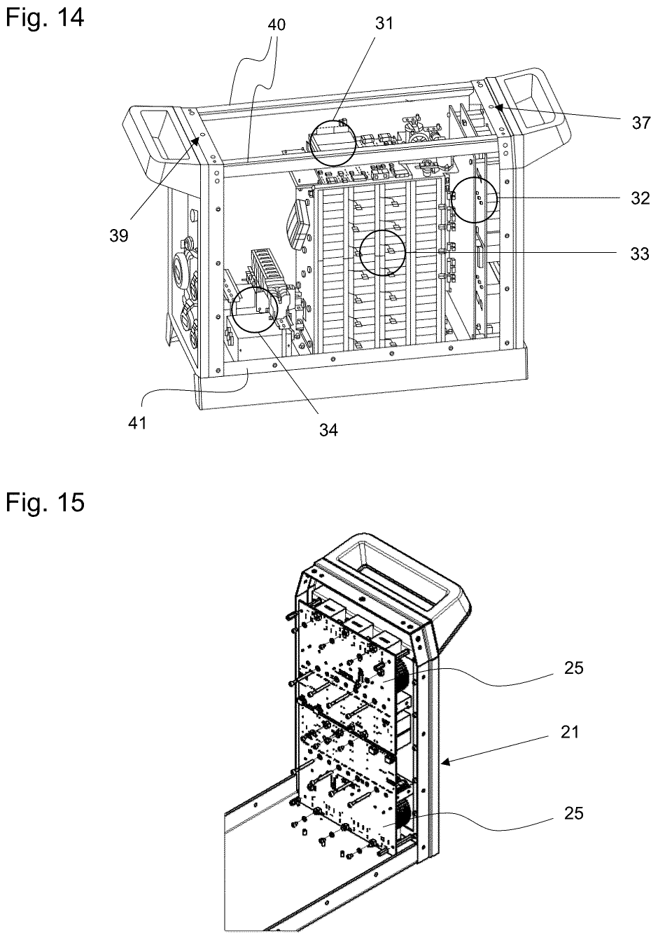

FIG. 14 shows a view of the internal components of the mobile rechargeable battery device on the side facing away from the side shown in FIG. 13;

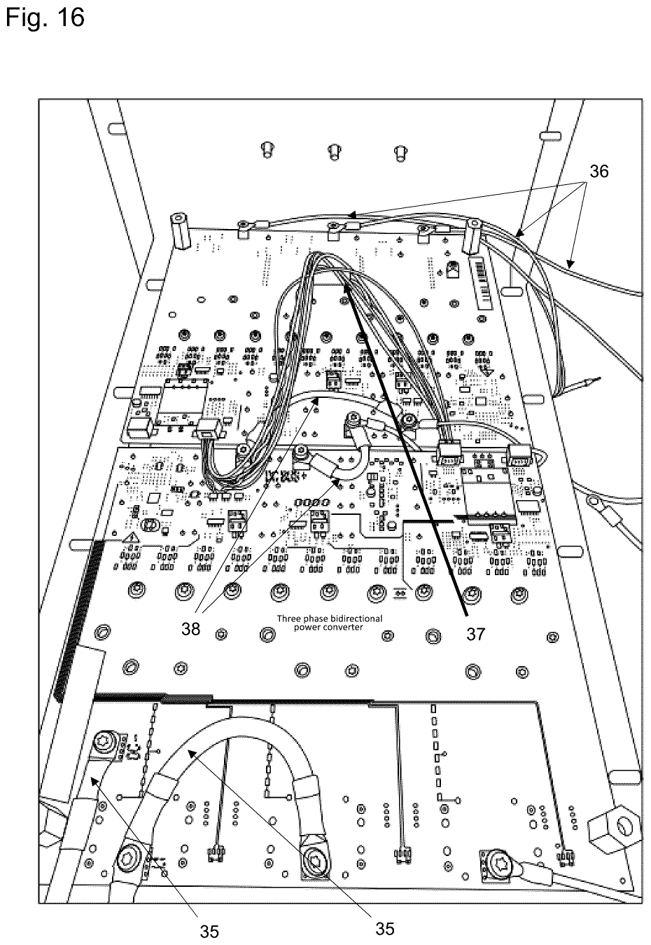

FIG. 15 shows a view of the circuit boards as they are to be screwed to the rear wall of the mobile rechargeable battery device;

FIG. 16 shows a view of the circuit boards mounted in the mobile rechargeable battery device;

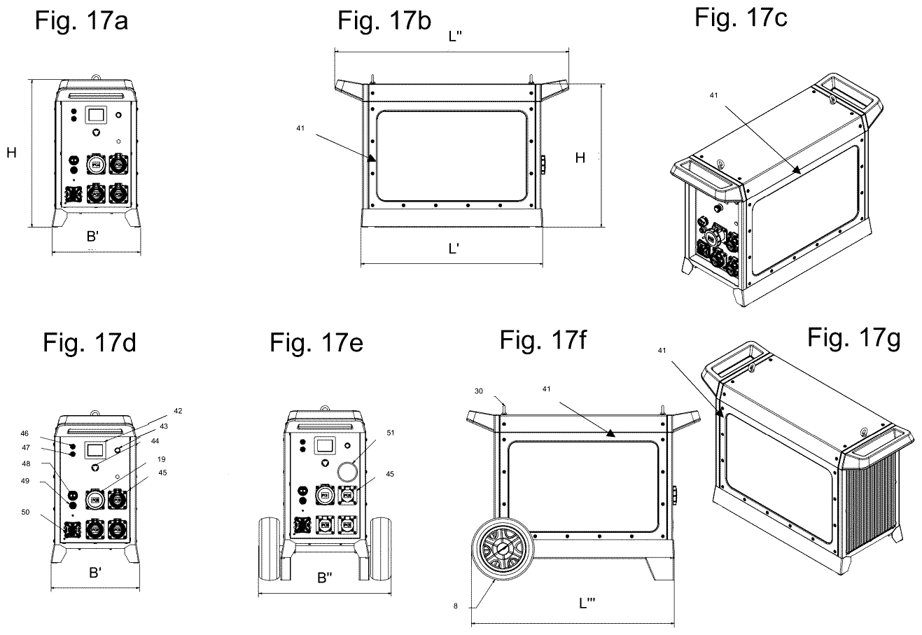

FIG. 17a-g shows the mobile rechargeable battery device with bearing strips and in another embodiment with wheels and support feet.

FIG. 1 shows a perspective view of an embodiment of the rechargeable battery device for providing three-phase alternating current independently of location. This mobile device comprises a substantially cuboid housing 1, the uppermost region of which is beveled towards the top. Alternatively, the housing can (e.g. additionally) be beveled at the bottom or can be purely cuboidal. Housing 1 accommodates a rechargeable battery pack, wherein the internal components of the device will be discussed later. Typical dimensions of housing 1, excluding any lifting handles, are in a range of no more than 900 mm for the length (L), no more than 400 mm for the width (B) and no more than 600 mm for the height (H). Depending on the case, the length (L) can also be understood as the height (H) or the height (H) as the depth (T), namely in the embodiment of the housing 1 as a square straight prism. In the embodiment shown here, the rechargeable battery device weighs only about 80 kg. Two opposing lifting handles 4, 5 are arranged at the top of the housing 1 and along its broad sides, allowing the device to be lifted and carried comfortably. These lifting handles 4, 5 are configured here in the form of bow handles. They can be fixed to the housing 1 or can be folded out. This means that the device can be lifted or carried to the required location by two men, each gripping one of the lifting handles 4, 5. Since it can be assumed that even an untrained person can lift a weight load of around 80 kg, the device can also be carried by just one person in an emergency, wherein the weight distribution is then optimally close to the body due to the lifting handles 4, 5 being arranged in this manner. In any case, a preferred embodiment of the rechargeable battery device weighs less than 100 kg and can be moved by a single person. A preferred dimension of the device housing 1, calculated without lifting handles 4, 5, is in the range of [650, 800] mm× [250, 350] mm× [450, 550] mm (L× W× H), which makes the housing particularly easy to handle. Preferably, the housing 1 is made of a stainless alloy, e.g. aluminum, and/or plastic.

Usually the rechargeable battery device is rolled for transportation, for which purpose it is configured as a hand-drawn trolley 3 having at least one wheel 8, 9 on the housing 1. In the present embodiment, a wheel 8, 9 is arranged at each of two adjacent lower corner regions 10, 11 of the housing 1, and these wheels are connected to a common axle 7 about which the device can be tilted. In FIG. 1, the rechargeable battery device is placed on its wheels 8, 9 and on the support feet 11, 12 located in the two adjacent corner regions at the front of the end face 15. On level ground, the hand-drawn trolley 3 therefore assumes a stable position when the housing 1 is in a horizontal position, for example when it is connected to one or more loads to draw power. For tilting or lifting and pulling the device, a swing-out or—as in the case shown—an extendable lifting handle 6 is provided on the side of the support feet 12, 13. The arrangement of the wheels 8, 9 in the corner regions 10, 11 optimizes the weight distribution when the device is lifted by the lifting handle 6.

If the rechargeable battery device is to be used outdoors, e.g. on open terrain or on construction sites, it is useful to have the baseplate 2 of the housing 1 at a vertical distance from the hand-drawn trolley 3 when it is parked on level ground. This allows the housing 1 to remain stable even on uneven ground when placed on its few bearing points 8, 9, 12, 13. This vertical spacing should ideally be at least 10 cm.

It will be understood that in alternative embodiments, the device may have more than two wheels 8, 9 or only a single wheel-similar to a single-wheeled wheelbarrow. The wheels 8, 9 or the individual wheel can also be rotatably mounted directly on the housing 1. The device according to the invention can also be configured such that it can be pushed like a wheelbarrow. The lifting handles on the housing 1 are then advantageously arranged in the same manner as those of a wheelbarrow. The device can also have only one support foot or more than two support feet.

FIG. 2 shows the hand-drawn trolley 3 in a perspective view seen from below, so that the lifting handle 6 with its plate 14 for tilting and pulling the device can be seen. This plate 14 can be pulled out by hand along a guide rail 16 with the end-side handle device mounted on it until it stops. In conjunction with the guide rail 16, the lifting handle 6 with its plate 14 can therefore be extended telescopically. Preferably, when the plate 14 is fully inserted into the guide rail 16, the lifting handle 6 does not protrude from below the baseplate 2 of the housing 1 or, in the case of support feet extending at an angle to the front, it does not protrude in relation to them. This means that the handle device is compact and safely stowed away. In one variant of the hand-drawn trolley 3, the plate 14 can be pulled out against a restoring force, which can ensure that the lifting handle 6 is securely accommodated when not in use so that no objects can get caught on it. It is understood that plate 14 can also be realized differently than shown here, for example in the form of two or more parallel rods, e.g. square tubes. The view according to FIG. 2 also shows the two wheels 8, 9 on the housing, which are connected to the housing by the wheel axle 7.

FIG. 3 shows a further embodiment variant of the mobile rechargeable battery device according to the invention in the form of a hand-drawn trolley 3, again in a perspective view. In contrast to the embodiment shown in FIGS. 1 and 2, a fold-out bow handle 18 is used here to tilt and pull the mobile rechargeable battery device. In this embodiment, the bow handle 18 is configured such that it can be accommodated in a recess in the end face 15 of the rechargeable battery device, preferably internally along the contour of the recess, and closes at most flush with the edge region of the end face 15. This means that when folded, the bow handle 18 is arranged in an optimal space-saving manner and cannot catch on any objects.

FIG. 4 shows the mobile device according to FIG. 3 being pulled or rolled on the ground by a person in the tilted state with the bow handle 18 fully extended. The folding up movement of the bow handle 18 is indicated by an arrow. The bow handle 18 can also be folded out against a spring force, for example. The fact that hinges are arranged at the upper corner regions of the recess on each bow end of the handle and are guided internally along its contour means that the handle 18 offers a long lever that makes maximum use of the height of the recess, which keeps the force to be applied by the person low. In an alternative embodiment, the bow handle 18 itself functions as an edge region of the end face 15 of the device, which maximizes the lever length or minimizes the force to be applied by a person.

FIG. 5 shows a mobile rechargeable battery device in a view of the end face 15 and provides a view of the switch plate 17. The outputs for connecting electrical loads are arranged on the same. The device according to the invention is primarily suitable for supplying loads for power-intensive applications with three-phase alternating current, also known as rotary current. For this purpose, the rechargeable battery device has at least one rotary current output 19 for receiving a corresponding rotary current plug. The rotary current output 19 can be recognized by the comparatively large hinged cover of the three-phase socket. Below this, three AC outlets, each with a single-phase socket, are arranged along the width of the switch plate 17. This means that the embodiment variant of the mobile rechargeable battery device shown here is therefore also suitable for supplying single-phase loads with electrical current. In addition, the switch plate 17 in this preferred embodiment also has a pressure relief valve (bottom right on the switch plate 17) and an emergency stop switch mounted here in the center, a connection for charging the device from the grid and an optional connection for a photovoltaic system as an additional charging option for the device. Preferably, a photovoltaic kit (PV kit) is available on the device itself for charging its rechargeable battery. The pressure relief valve acts as a safety mechanism and opens to release excess pressure in the rechargeable battery before dangerous situations such as explosions or fires can occur. A display is advantageously arranged on the switch plate 17 for displaying information on the operation of the rechargeable battery device. In this example, the latter is configured as a touchscreen for operating the device and selecting settings, usage modes and the like. Of course, the switches, sockets, displays and all features for setting modalities and/or maintenance can also be arranged or implemented alternatively and in different numbers in a switch plate 17. In particular, the switch plate 17 can also have more than one rotary current output.

The accommodation of all outputs for the connections, switches, display, operating and setting modalities on a single switch plate 17 in the housing 1 enables a particularly space-saving configuration. Preferably, this switch plate 17 is recessed in a recess of the end face 15 of the device, so that all its components, and in the case of protective hinged covers on the sockets preferably including the same, are enclosed by the housing 1 or by the edge of the end face 15 and do not protrude.

Another variant of the mobile rechargeable battery device according to the invention without wheels is shown in FIG. 6. Instead of wheels 8, 9 and support feet, this embodiment variant is based on bearing strips. This device is transported by one or more people using the lifting handles 4, 5. It is particularly suitable for applications where movement on wheels 8, 9 is not possible or only with difficulty or is simply not necessary.

FIG. 7 provides a perspective view of the side of the mobile rechargeable battery device facing away from the end face 15, in this case the side with the wheels 8, 9. This side shows the part of the heatsink 21 that is visible from the outside. The cooling surface 20 formed by the cooling fins can be seen. This results in total as the sum of the surfaces of the inwardly projecting cooling fins 22, shown here only at their vertical end edges, and the other invisible surfaces on the heatsink 12, via which waste heat is emitted to the outside into the ambient air. By appropriately dimensioning the heatsink 21 with a sufficiently large surface area, it may be possible to dispense with a fan for increasing the air flow through the cooling fins 22 and thus increasing the dissipation of heat to the environment. According to this type of cooling of the rechargeable battery device, no ventilation slots are required in the housing 1, which means that, apart from openings for outputs for loads, switches and communication interfaces, it can be closed on all sides, except for any one-way outlets for a pressure relief valve and/or a rainwater outlet. Preferably, a hydraulic connection with hose can be used for a rainwater outlet, which allows rainwater to flow in one direction only. Openings for one-way outlets are configured correspondingly small. In particular, the housing 1 can be configured to be dust-tight. Advantageously, the housing 1 of the mobile rechargeable battery device is configured to be closed except for the openings mentioned. A small number of openings in the housing 1 also contributes to a low noise emission of the rechargeable battery device. Furthermore, the more efficient the heatsink 21 is, the less power is required from an additional fan, which is generally the largest source of noise emissions in a rechargeable battery device. In the best case, or with an appropriately dimensioned heatsink 21, a fan can be dispensed with altogether. The absence of openings in the housing 1, apart from openings for outputs for loads, switches and communication interfaces and for any one-way outlets, proves to be particularly advantageous for use of the device according to the invention in humid and/or dust-laden localities, e.g. on construction sites or the like. In particular, the rechargeable battery device can then be operated at a relative humidity of at least up to 95%. It is understood that the cooling variant with heatsink 21 shown here can be used on any embodiment of the rechargeable battery device, of course also on a wheel-less variant as shown in FIG. 6. In particular, the heatsink 21 can also be configured such that it forms outwardly projecting cooling fins 22 on other sides of the rechargeable battery device in order to increase the cooling surface 20.

To increase heat dissipation to the outside, minimal air slots can be provided in housing 1, but these are only large enough to allow the air flow required for cooling to be discharged to the outside and new ambient air to be drawn in through other slots. These ventilation slots are configured such that, as far as possible, they do not result in a higher classification of the device for protection against foreign bodies and contact and for protection against water than the device must fulfill for the respective requirements. The air slots are dimensioned such that a solid foreign object of a certain diameter cannot pass through them. Depending on the case, the air slots provide protection against a solid foreign body, the diameter of which is typically one of the values {2.5 mm, 2.25 mm, 2 mm, 1.75 mm, 1.5 mm, 1.25 mm, 1 mm, 0.75 mm}. Apart from openings for loads and switch outputs, the housing 1 of the rechargeable battery device according to the invention can be closed except for such minimal openings for air exchange and any openings for one-way outlets (such as a pressure relief valve or a rainwater outlet). In damp and/or dusty locations, an air-permeable membrane or filter should be fitted in place of such cooling openings to keep water, dirt and other foreign bodies out.

In FIG. 8, the numerous inwardly projecting cooling fins 22 or cooling ribs of the heatsink 21 can be seen on the side of the rechargeable battery device facing away from the end face 15. The heatsink 21 is advantageously anodized, which allows it to dissipate more heat through thermal radiation due to the porosity of the surface. A black anodized layer leads to a higher absorption of radiant heat due to its color. Black color has the property of absorbing a larger bandwidth of the electromagnetic spectrum and converting it into heat. This further increases the heat dissipation from the inside of the device due to radiation. The cooling fins 22 are advantageously integrally molded to a rear plate as a rear cooling plate or at least connected with good thermal conductivity, wherein the rear plate in turn connects to the components of the power electronics, as will be explained later. Depending on the embodiment and dimensioning of the heatsink 21, e.g. by extending the cooling surface 20 to regions of the longitudinal sides of the device which connect at right angles to the side shown in FIG. 8, a blower or fan can also be dispensed with completely in the housing 1 of the device. The passive dissipation of waste heat via the heatsink 21 is then sufficient to cool the device, so that, depending on the case, no fan is required or only a fan with a low volume flow is sufficient to support the cooling. This means that the device according to the invention can be operated or charged and discharged with little or no background noise. In particular, this opens up fields of application where even small background noises are particularly disturbing, such as during music, sound or speech playback.

FIG. 9 shows a cross-section of a preferred embodiment of heatsink 21 with its fins 22 projecting vertically from the back plate. It can be seen here that the fins 22 are specially structured, namely corrugated, to increase the cooling surface 20. Advantageously, the number of cooling fins 22 on the heatsink 21 is between 30 and 70. Preferred value ranges for the mass are listed below:
m1: [0.5 cm, 1 cm],
m2: [0.1 cm, 0.3 cm],
m3: [1.5 cm, 5 cm],
m4: [0.5 cm, 1.5 cm]
m5: [20 cm, 50 cm].

In one variant, the heatsink 21 is U-shaped with right angles so that it at least partially follows the contours of the housing. This further increases the cooling surface 20 for the most pronounced to completely passive cooling of the rechargeable battery device. Heatsinks 21 in profile form can be extruded and are therefore simple and cost-effective to manufacture. A rechargeable battery device can also include a plurality of heatsinks 21 or a heatsink 21 with a plurality of individual components, which are advantageously connected to one another via thermal bridges. The weight of the heatsink 21 in the mobile rechargeable battery device is advantageously not more than 7.5 kg, and further preferably not more than 5 kg.

As already mentioned, the heatsink 21 can interact with a fan to achieve air circulation inside the housing. The cooling of the rechargeable battery device realized in this manner is a cooling with circulating air, wherein waste heat is passively emitted to the outside, so that no exchange with the ambient air takes place. The internal structure of such a mobile rechargeable battery device with heatsink 21 and fans 23 for circulating air cooling in the housing 1 is shown as an example in FIG. 10. The heatsink 21 here consists of two components, each of which comprises a plurality of cooling fins 22 which provide a large cooling surface, so that the two fans 23 used here each have a power of at most 2 W, and advantageously of even at most 1.5 W. In a preferred embodiment of the rechargeable battery device for minimizing noise emissions, the presence of a fan 23 is completely dispensed with and cooling is ensured solely by the heatsink 21. Generally speaking, the higher the capacity and the current flow of the rechargeable battery, the higher the power required by the fan 23. FIG. 10 also shows the rechargeable battery pack with its plurality of accumulator cells 24 and two power modules 25 or component-assembled circuit boards for the power converters. The term power module is used here to refer to a component-assembled circuit board. The connections leading to the sockets in the end face 15 of the housing 1 are not shown here. The at least one rotary current output 19 for providing rotary current independently of location, of which such a device can also have several, is again prominently visible. The switch plate 17 is not shown here.

FIG. 11 shows another variant of a mobile cuboid rechargeable battery device with a larger width edge compared to its height edge. In this alternative arrangement, the cooling fins 22 of the heatsink 21 run parallel to the width edge of the device. The outputs, again shown here without the switch plate 17, are also arranged somewhat differently than in the previous example according to FIG. 10, which illustrates the arbitrary nature of their arrangement. It is understood that the number of sockets and outputs can also vary here. In an alternative embodiment of the rechargeable battery device, in particular for noise-sensitive applications, the fan 23 can be dispensed with. However, it is advantageous to have a low power fan 23 that remains switched off when not required.

As a special feature, the rechargeable battery device according to the invention opens up the field of application of high-voltage batteries or high-voltage rechargeable batteries/accumulators, respectively, for the mobile energy supply sector. High-voltage systems or high-voltage (HV for short) are systems that are operated with alternating current voltages above 30 V up to 1 kV or with direct current voltages above 60 V up to 1.5 kV. The term high-voltage used here comes from automotive engineering and is therefore referred to as “high” because such voltages are dangerous for humans. A battery or rechargeable battery/accumulator, respectively, is a direct current source, which means that the term high-voltage battery or rechargeable battery/accumulator, respectively, is based on its direct current voltage (wherein the nominal voltage is used). As a substantial advantage of the high electrical voltage U of a high-voltage battery or rechargeable battery/accumulator, respectively, the electrical current I is comparatively low for a given electrical power P (P=U−I). For applications, this means that the same power can be realized more easily in a high-voltage system than with the difficult-to-handle high currents in a low-voltage system. For example, thinner cables with a smaller conductor cross-sectional area can be used for high voltages and correspondingly low currents. This sometimes allows savings to be made on materials and cooling and enables significant weight savings. So far, however, high-voltage batteries have primarily been installed in electric vehicles or used as stationary storage for solar applications. One reason for this limited application is that it is a technological challenge to provide the safety requirements applicable due to the higher voltage and the necessary components in a compact construction and at a relatively low weight so that the manageability of the device is not compromised. Advantageously, the total weight of the device according to the invention should be less than 100 kg so that it can be lifted by a single person if necessary and can easily be carried over longer distances by two people.

Against the background of the previous use of high-voltage rechargeable batteries, the mobile rechargeable battery device according to the invention breaks completely new ground when, in a preferred variant, it provides a rechargeable battery pack with a high-voltage nominal voltage, i.e. with a nominal voltage of more than 60 V, for the field of mobile applications, with manual transportability of the device, sometimes for outdoor use.

FIG. 12 shows the circuit diagram of the electronics according to a preferred embodiment of the mobile rechargeable battery device. The abbreviations mean the following:
HMI=Human Machine Interface
CAN=Controller Area Network
Iso monitor=Insulation monitoring device
BMS=Battery Management System
Bidir. inverter=bidirectional inverter
Bidir. DC/DC=bidirectional DC/DC converter
BAT+=positive battery terminal
BAT−=negative battery terminal
AI=Analog Input
HV=High-Voltage.
C[ . . . ]=Cell (accumulator cell), [ . . . ]=identification numbers of the accumulator cells
DI, DO=Digital Input, Digital Output

The power electronics here include a BMS master, namely a main control unit that coordinates communication with the four BMS slaves and manages all the important functions of the BMS. The BMS master can then make decisions to optimize the power and safety of the rechargeable battery by controlling the charging and discharging processes and issuing warnings if problems occur. This ensures that the rechargeable battery operates within specified limits. For this purpose, the BMS master collects and analyzes the data supplied by the BMS slaves as small, autonomous monitoring units, such as the voltage, current, temperature and status of each rechargeable battery cell 24 of the rechargeable battery. The BMS slaves are arranged near the accumulator cells 24 for this purpose. They can also make local decisions to ensure the safety of cells 24, such as switching off cells 24 if their voltage is outside the permissible range. The master-slave system allows the rechargeable battery system to be operated efficiently and precisely. It also provides redundant monitoring capabilities by allowing multiple monitoring units to collect and analyze the same information to increase system reliability and security. The HMI or user interface gives the user easy access to information about the rechargeable battery status and control of the charging and discharging processes. The HMI displays important information such as the current rechargeable battery status, the remaining rechargeable battery capacity, the charging and discharging power and the temperature. The user can also set parameters such as the maximum charging voltage, the maximum discharging voltage and the maximum charging or discharging power of the rechargeable battery.

Furthermore, for the power electronics in the rechargeable battery device according to the invention, two modules 25, i.e. component-assembled circuit boards, are preferably used for the power converters. The two modules are then programmed so that one module works as a bidirectional DC/DC converter and the other as a bidirectional three-phase inverter, which are installed in one unit. They work together to enable bidirectional conversion between three-phase alternating current and direct current. This “integrated” embodiment offers a compact construction. The inverter preferably comprises a bidirectional three-phase full bridge.

A transformerless embodiment of the inverter proves to be advantageous because it saves weight. In order to ensure that a desired output voltage of e.g. 400 V is provided for power-intensive applications, the comparatively low rechargeable battery voltage, which is e.g. 200 V, must be stepped up by the DC/DC converter to an intermediate DC voltage. Finally, the inverter converts it into the corresponding output AC voltage. The voltage stepped up by the DC/DC converter must be higher than the output voltage of 400 V to be provided here, so that the DC/DC converter can preferably step up the voltage to at least 600 V or at least 650 V.

Thanks to its safe and efficient constructive design, the rechargeable battery device according to the invention achieves an unprecedentedly high ratio of the gross capacity of the rechargeable battery or rechargeable battery pack (as the amount of electrical charge that the rechargeable battery of the device can store) to the residual weight of the mobile rechargeable battery device, i.e. to the total weight of the mobile rechargeable battery device minus the rechargeable battery weight, thus minus the weight of the rechargeable battery pack and, in the case of a plurality of rechargeable battery packs, minus the weight of all rechargeable battery packs. This ratio of the rechargeable battery capacity to the residual weight of the mobile rechargeable battery device according to the invention achieves energy densities of at least 0.1 kWh/kg. Preferably, this ratio even achieves energy densities of at least one of the following values: {0.125 kWh/kg, 0.15 kWh/kg, 0.175 kWh/kg, 0.2 kWh/kg, 0.225 kWh/kg, 0.25 kWh/kg}. With a total weight of the rechargeable battery device according to the invention of about 80 kg, a rechargeable battery pack with a weight of about 40 kg meets a residual weight of the device of only about 40 kg. With a rechargeable battery capacity of 8 kWh, this corresponds to an energy density of the mobile rechargeable battery device in relation to the residual weight, i.e. the ratio of rechargeable battery capacity: residual weight, of 8 kWh: 40 kg=0.2.

Further preferably, the rechargeable battery device according to the invention additionally fulfills the following condition with regard to energy density: The ratio of the rechargeable battery capacity to the residual weight of the mobile rechargeable battery device, i.e. to the total weight of the mobile rechargeable battery device, minus the weight of the rechargeable battery pack and, in the case of a plurality of rechargeable battery packs, of all rechargeable battery packs and further minus the weight of the housing 1 without heatsink 21, achieves energy densities of at least 0.2 kWh/kg. This additional condition expresses how low the weight of the internal components of the mobile rechargeable battery device, regardless of the rechargeable battery weight, is for the available energy capacity of the rechargeable battery. With a total weight of the mobile rechargeable battery device according to the invention of about 80 kg and a housing 1 without heatsink 21 of about 15 kg, a rechargeable battery with a weight of 40 kg has a residual weight of the device of just 25 kg (=80 kg-15 kg-40 kg) and achieves an energy density of 0.3 kWh/kg with a rechargeable battery capacity of 8 kWh. According to the invention, the device can achieve an energy density in relation to the residual weight minus the weight of the device housing 1 of at least 0.2 kWh/kg, and preferably one of the following minimum values {0.225 kWh/kg, 0.25 kWh/kg, 0.275 kWh/kg, 0.3 kWh/kg, 0.325 kWh/kg}. This makes the device an extremely lightweight, highly efficient mobile energy source for three-phase loads and enables it to be used even in remote locations.

In particular, an optimized such ratio is achieved by using a high-voltage rechargeable battery. Preferably, the nominal voltage of the rechargeable battery pack used in the mobile rechargeable battery device is then more than 60 V, and further preferably equal to or more than 100 V. Preferred embodiments of the device according to the invention use a rechargeable battery pack with a nominal voltage value of equal to or more than 150 V or further preferably equal to or more than 200 V. This also applies when a plurality of rechargeable battery packs is used in the device.

FIG. 13 shows the inside of the mobile rechargeable battery device. On the side or rear facing away from the end face 15, the heatsink 21 can be seen with its inner cooling plate, to which the power modules 25 are connected via thermal bridges. The fans 23 circulate air inside the housing 1 to increase the cooling effect as required. Also shown is the region 26 with the BMS, insulation monitor and battery electronics on different circuit boards as well as the region with safety elements 27. For reasons of redundancy, two different current sensors are preferred in the present rechargeable battery system, e.g. a Hall sensor and a shunt sensor. Advantageously, two relays and a fuse are installed as protection. The number of circuit boards depends on the configuration of the power electronics. It would also be possible to fit everything onto one circuit board. Also shown is the advantageous arrangement of one or more common mode filters 29 to reduce interference and improve electromagnetic compatibility (EMC) as well as one or more contactors 28. Furthermore, it can be seen in FIG. 13 that the housing 1 is equipped with an eyelet 30 on the wide side of the device. Such eyelets 30 are optionally available if the device is to be transportable by crane. The device housing 1 is reinforced here by cross struts 40 and a box frame 41.

FIG. 14 shows an interior view of a wheel-less mobile rechargeable battery device on bearing strips, looking towards the other side of the device compared to the view according to FIG. 13. This makes it easy to see, among other things, the region 34 with two common mode filters 29, a single-stage and a two-stage common mode filter, and contactors 28. Only one common mode filter 29 would also be possible. This helps to reduce electromagnetic interference (EMI) and noise. A common mode filter removes common mode interference by providing a high resistance for signals that are the same on both conductors (common mode). The power modules 25 visible in front of the heatsink 21 are described below. Advantageously, the device housing 1 is prepared with nuts 39 in corresponding bores of the housing 1 for mounting or screwing in a suitable lifting device such as an eyelet 30. The housing 1 is sturdily built so that it meets the requirements of a vibration test. For the embodiment of the device shown here, the struts 40 and frame reinforcements 41 have been used to create a particularly robust housing 1, in particular with regard to possible crane transport of the device. Furthermore, circled in FIG. 14 are the rechargeable battery electronics 31, the power electronics 32 with rotary current inverter and DC/DC converter, the rechargeable battery pack 33 and electromechanical components 34, including contactor 29.

FIG. 15 indicates how the power modules 25 are mounted to the circuit boards by means of set screws so that, when mounted, they connect to the back plate of the heatsink 21 of the device, directly and/or indirectly via thermal bridges. Thermal bridges can be formed, for example, by thermally conductive gap filling material, which hardens at room temperature or at a higher temperature (with hot air) in an irreversible curtain. This arrangement of the power modules 25 for the power converters at the rear of the mobile rechargeable battery device enables space-saving accommodation of the internal components and a compact arrangement of the heatsink 21. The power modules 25 can have different dimensions and arrangements, which also applies to the heatsink 21.

FIG. 16 shows the circuit boards of the modules 25 with their electronic components and connections. The modules here are bidirectional AFE modules (AFE for Active Front End). In general, an AFE is used to improve power factor correction (PFC) and at the same time reduce harmonics and interference in the current supply. It is a power electronic circuit that enables bidirectional energy flow control and efficient conversion between different voltage and current levels. The modules can be operated as boost, buck or PFC converters (boost=voltage increase, buck=voltage reduction, PFC=Power Factor Correction). The thick cables 35 at one end of the lower circuit board here are the connecting cables to the rechargeable battery pack; at the opposite end of the other circuit board are the cables 36 that connect to the common mode filter 29. Also visible is a so-called daisy chain 37, i.e. a serial connection between the two modules for the transmission of data and control signals or communication. The two cables 38 located nearby are bridging cables between the modules with a discharge resistor.

As an example, the following specifications are given with preferred bandwidths of their values for embodiments of the mobile rechargeable battery device according to the invention.

Rechargeable battery

| | |
|---|---|
| Gross capacity | 6-11 kWh |

Mechanical data

| | |
|---|---|
| Total weight | 70-99 kg |
| with an energy density in | ≥0.1 kWh/kg |
| relation to the residual weight | |
| (=weight of the device minus | |
| weight of the rechargeable | |
| battery) of | |
| and optionally additionally | ≥0.2 kWh/kg |
| with αν energy density in | |
| relation to the residual weight | |
| (=weight of the device minus | |
| the weight of the rechargeable | |
| battery minus the weight of the | |
| housing without heatsink 21) of | |
| Dimensions | L: 300-900 mm |
| | B: 300-400 mm |
| | H: 400-600 mm |
| Housing | (preferably stainless) alloy |
| | and/or plastic |

In addition, the mobile rechargeable battery device according to the invention is characterized by the following advantageous features, individually or in any combination:
a continuous discharge capacity of 8-15 KVA;
the option of charging the rechargeable battery with direct current;
a GPS module on the device;
charging option via a PV kit attached to the device;
possibility of parallel charging and discharging (grid parallel mode);
possibility of connecting two mobile rechargeable battery devices in parallel to expand the capacity provided by the rechargeable batteries individually;
manual transportability of the device;
crane transportability of the device.

In particular, a preferred embodiment of the mobile rechargeable battery device according to the invention has one or more or any combination of the features listed below:

Electrical data
Rechargeable battery

| | | |
|---|---|---|
| Gross capacity¹ | 8.9 | kWh |
| Net capacity² | 8 | kWh |

| | |
|---|---|
| Cell technology | Lithium-ion NMC (nickel manganese |
| | cobalt oxides) |
| Life expectancy | up to 1,000 cycles, >70% SoH |
| Charging methods | 230 V, 3 × 400 V, PV kit (Q4/2023), |
| | DC charger (Q4/2023) |
| Charging time (standard)³ | 5 h (230 V/Schuko DE or T13 CH) |
| Quick charge³ | 2 h (400 V/CEE16) |

Power electronics

| | | |
|---|---|---|
| Max. discharge power⁴ | 13 | kW |
| Discharge power (continuous) | 11 | kW |
| Max. charging power | 4.4 | kW |

| | |
|---|---|
| Output data and connector⁶ | 3/N/PE AC 400 V 50 Hz (CEE16) 1/N/PE |
| | AC 230 V 50 Hz (3 connections CEE7), |
| | optionally Schuko DE and T23 CH |
| Input data and connector | 3/N/PE AC 400 V 50 Hz (CEE16) 1/N/PE |
| | AC 230 V 50 Hz (Schuko DE or T13 CH) |
| Overcurrent protection device | Short-circuit protection and |
| | electronic fuse (B16) |
| Cooling | Passive |
| Efficiency⁷ | >95% |

User interface

| | |
|---|---|
| Operation | On-Off button |
| Display | Touchscreen (TFT) for information |
| | and input |
| Information | Charging status (SoC), operating mode, |
| | output power, charging power, operating |
| | time, charging time |
| Warnings | Over- and under-temperature, charge |
| | status, overload, output power reduction, |
| | emergency stop status |
| Error | Over- and under-temperature, overload, |
| | undervoltage, faulty components, |
| | insulation faults |

Mechanical data

| | | |
|---|---|---|
| Total weight⁸ | 80 | kg |

| | |
|---|---|
| Dimensions L × W × H⁹ | 944 × 357 × 596 mm |
| Charge temperature range | 0° C. to +40° C. |
| Discharge temperature range | −10° C. to +45° C. |
| Storage temperature | 1 month at 0° C. to +45° C., |
| | 3 months at 0° C. to +25° C. |
| Degree of protection | IP65 (dust and water jet protection) |
| Housing | Stainless alloy and plastic |
| Relative air humidity | 5-95% |

Safety

| | |
|---|---|
| Battery management | SIL2 level |
| system (BMS)¹⁰ | |
| Safety functions | All-pole disconnection, over- and under- |
| | temperature cut-off, over- and |
| | undervoltage cut-off, redundant |
| | overcurrent cut-off, patented overcurrent |
| | protection per battery cell, insulation |
| | monitoring |
| Compliance | RoHS, CE |
| Certification | EN 62477-1, EN 62040-1, UN38.3 |

¹Standard charge 0.2 C, 25° C./discharge at 0.2 C, 25° C.
²Standard charge 0.2 C, 25° C./discharge at 0.5 C, 25° C.
³Up to 90% SoC
⁴For 10 seconds, cos(φ) 0.7 . . . 1
⁵ cos(φ) 0.7 . . . 1
⁶Other connector types on request
⁷At nominal power
⁸Without wheels, cables and attachments
⁹Without wheels and cables
¹⁰Integrated according to the IEC 61508 standard

FIGS. 17a-c show an embodiment of the mobile rechargeable battery device with bearing strips located at the bottom of the device. Whereas FIGS. 17d-g show the mobile rechargeable battery device with wheels and adjustable feet. In both embodiments of the device, optional eyelets 30 are screwed into the top of the housing 1 on its wide sides for any crane transport of the device. They can be removed when not needed. The housing 1 of the device is advantageously reinforced with a box frame 41. Inside, it can be provided with struts 40 to further increase its stability. FIGS. 17a, 17b, 17d-f show the dimensions H, B′, B″, L′, L″ and L′″. B′ denotes the width of the device including the bearing strips and is advantageously between 300 and 450 mm, while B″ denotes the width of the device including its wheels 8, 9 and is advantageously between 500 mm and 650 mm. L′ denotes the length of the device without lifting handles 4, 5, L″ the length including lifting handles 4, 5 and L′″ the length including the wheels 8, 9 and the support feet 12, 13. Advantageous dimensions for L′ are between 650 mm and 850 mm, for L″ between 850 mm and 1050 mm, and for L′″ between 750 mm and 950 mm. Also shown in FIG. 17d are: a display 42 for the user interface (e.g. a touch display for selecting functions of the device), an on/off switch 43, an emergency stop switch 44, a rotary current output or rotary current socket 19, a single-phase socket 45 of a total of three such sockets, a CAN output 46, a 24 V output 47, which can also be configured for a different voltage as required, an output 48 for PV charging or DC charging, a charging cable socket 49 and a pressure relief or safety valve 50, which encloses an elastic membrane and opens to release pressure when it exceeds a critical value and closes again when the pressure has dropped to a safe level. FIG. 17e also shows a GPS antenna 51 above the uppermost single-phase socket 46. It is understood that the mentioned outputs for loads, switches and communication interfaces on the device according to the invention are independent of whether a specific device has wheels 8, 9 and support feet 12, 13 or bearing strips, eyelets 30 or no eyelets 30 or whether the housing is reinforced with a box frame 41 as shown, etc.

The device according to the invention enables a rechargeable battery or rechargeable battery pack to be converted into a mobile energy supply apparatus for power-intensive indoor and outdoor use in a small space and with minimum weight. The quality of the residual weight of a mobile rechargeable battery device is proven when a rechargeable battery or rechargeable battery pack with a high gross capacity can be installed in a power-intensive field of application with minimal space requirements and weight increase to form a mobile power supply unit. For this purpose, the rechargeable battery device according to the invention makes it possible to use high-voltage rechargeable batteries in particular, which are safely installed and compactly housed in it with minimal weight. Due to its low weight and small volume, the rechargeable battery device according to the invention can be moved by hand to virtually any location and thus opens up new areas of application that previously made the use of industrial load devices considerably more difficult, if not impossible. For example, areas of application include construction sites, events of all kinds, campsites, terrain and forest areas, mountain areas, in particular remote locations or places that are difficult to access due to disasters, for example. The rechargeable battery device is also suitable as an emergency power generator, for example when energy is in short supply in winter or when the power grid is overloaded, to ensure an uninterrupted power supply wherever it is needed.

The object of the invention is furthermore achieved by the advantageous embodiments of the mobile rechargeable battery device according to the invention, as described below, namely by a mobile rechargeable battery device having the features according to any of claims 1 to 18, wherein the mobile rechargeable battery device further has a feature or any combination of features according to the following paragraphs, namely . . .

. . . wherein the energy density of the rechargeable battery device in relation to its residual weight, which corresponds to the total weight of the rechargeable battery device minus the weight of the rechargeable battery pack or, in the case of a plurality of rechargeable battery packs, of all the rechargeable battery packs, thus the gross capacity of the rechargeable battery pack or, in the case of a plurality of rechargeable battery packs, their total gross capacity divided by the residual weight is at least one of the values {0.125 kWh/kg, 0.15 kWh/kg, 0.175 kWh/kg, 0.2 kWh/kg, 0.225 kWh/kg, 0.25 kWh/kg}.

. . . wherein the gross capacity of the rechargeable battery pack or, in the case of a plurality of rechargeable battery packs, their total gross capacity divided by the weight, which is calculated as the residual weight minus the weight of the housing 1 without heatsink 21, is at least one of the values {0.15 kWh/kg, 0.175 kWh/kg, 0.225 kWh/kg, 0.25 kWh/kg, 0.275 kWh/kg, 0.3 kWh/kg, 0.325 kWh/kg}.

. . . wherein the gross capacity of the rechargeable battery pack or, in the case of a plurality of rechargeable battery packs, their total gross capacity divided by the weight of the one heatsink 21 or, in the case of a plurality of heatsinks 21, of all heatsinks 21 is at least one of the values {0.75 kWh/kg, 1.25 kWh/kg, 1.5 kWh/kg, 1.75 kWh/kg, 2 kWh/kg, 2.25 kWh/kg, 2.5 kWh/kg}.

. . . wherein the proportion of weight of one heatsink 21 or, in the case of a plurality of heatsinks 21, of all heatsinks 21 in the total weight of the rechargeable battery device is not more than one of the values {10%, 9%, 8%, 7%, 6%, 5%}.

. . . wherein the one or, in the case of a plurality of heatsinks 21, these heatsinks 21 have a total thermal resistance (K/W) which, depending on the weight of the heatsink 21 m_{K} in kg or, in the case of a plurality of heatsinks 21, their total weight m_{K} in kg is less than −0.02 K/(W·kg) m_{K}+0.3 K/W.

. . . wherein the rechargeable battery device is cooled exclusively by air cooling.

. . . wherein, starting from a power loss of the one or, in the case of a plurality of rechargeable battery packs, the rechargeable battery packs as a whole this outgoing power loss is reduced by creating a variable DC link voltage and/or by reducing an output voltage of the rechargeable battery pack or rechargeable battery packs by at least one of the values {10%, 12.5%, 15%, 17.5%, 20%} compared with the outgoing power loss.

. . . wherein the gross capacity of the rechargeable battery pack or, in the case of a plurality of rechargeable battery packs, their total gross capacity divided by the weight of the one common mode filter 29 or, in the case of a plurality of common mode filters 29, of all common mode filters 29 is at least one of the values {1.75 kWh/kg, 2 kWh/kg, 2.25 kWh/kg, 2.5 kWh/kg, 2.75 kWh/kg, 3.25 kWh/kg, 3.5 kWh/kg, 3.75 kWh/kg, 4 kWh/kg, 4.25 kWh/kg, 4.5 kWh/kg, 4.75 kWh/kg, 5 kWh/kg}.

. . . wherein the rechargeable battery device includes at least one single-stage and one two-stage common mode filter 29.

. . . wherein the rechargeable battery device includes one or more fans 23 for circulating air cooling in the housing 1, with such a maximum power of the one fan 23 or, in the case of a plurality of fans 23, with such a maximum total power that the gross capacity of the rechargeable battery pack or, in the case of a plurality of rechargeable battery packs, their total gross capacity divided by the maximum power of the one fan 23 or, in the case of a plurality of fans 23, their maximum total power is at least one of the values {1500 h, 2000 h, 2500 h, 3000 h, 3500 h, 4000 h, 4500 h}.

. . . wherein the power of the one fan 23 or, in the case of a plurality of fans 23, the total power of the plurality of fans 23 is not more than one of the values {1 W, 2 W, 3 W, 4 W, 5 W, 6 W, 7 W, 8 W, 9 W, 10 W}.

. . . wherein the housing 1, irrespective of openings for outputs for loads, switches and communication interfaces, is closed, except for openings for one-way outlets and/or openings for cooling with the ambient air, wherein the cooling openings are dimensioned such that a solid foreign body whose diameter is at least one of the values {0.5 mm, 0.75 mm, 1.25 mm, 1.5 mm, 1.75 mm, 2 mm, 2.25 mm, 2.5 mm} cannot pass through them.

. . . wherein the total weight of the rechargeable battery device is less than one of the values {120 kg, 115 kg, 110 kg, 105 kg, 100 kg, 95 kg, 90 kg, 85 kg, 80 kg}.

. . . wherein the nominal voltage of the rechargeable battery pack or, in the case of a plurality of rechargeable battery packs, of each rechargeable battery pack is at least one of the values {60 V, 80 V, 100 V, 125 V, 150 V, 175 V, 200 V}.

. . . wherein the gross capacity of the rechargeable battery pack or, in the case of a plurality of rechargeable battery packs, of the rechargeable battery packs as a whole is at least one of the values {6 kWh, 6.5 kWh, 7 kWh, 7.5 kWh, 8 kWh, 8.5 kWh, 9 kWh}.

. . . wherein the gross capacity of the rechargeable battery pack or, in the case of a plurality of rechargeable battery packs, of the rechargeable battery packs as a whole is at most one of the values {10 kWh, 10.5 kWh, 11 kWh, 11.5 kWh, 12 kWh, 12.5 kWh, 13 kWh, 13.5 kWh, 14 kWh, 14.5 kWh, 15 kWh, 16 kWh, 17 kWh, 18 kWh, 19 kWh, 20 kWh}.

. . . wherein the rechargeable battery device includes a bidirectional DC/DC converter.

. . . wherein the rechargeable battery device includes a bidirectional DC/DC converter, and the nominal voltage of the rechargeable battery pack or, in the case of a plurality of rechargeable battery packs, of each rechargeable battery pack is at most one of {200 V, 250 V, 300 V, 350 V, 400 V, 450 V, 500 V, 550 V, 600 V}.

. . . wherein the three-phase inverter comprises a bidirectional three-phase full bridge.

. . . wherein the thickness of the plates forming the housing 1 is at least one of the values {1 mm, 1.25 mm, 1.5 mm, 1.75 mm, 2 mm}.

. . . wherein the housing 1 is substantially cuboidal or purely cuboidal, with a length of the housing 1 of at most one of the values {1200 mm, 1150 mm, 1100 mm, 1050 mm, 1000 mm, 950 mm}, a width of the housing 1 of at most one of the values {700 mm, 650 mm, 600 mm, 550 mm, 500 mm, 450 mm} and a height of the housing 1 of at most one of the values {900 mm, 850 mm, 800 mm, 750 mm, 700 mm, 650 mm}.

. . . wherein the housing 1 is made of sheet metal or plastic.

. . . wherein the housing 1 is made of sheet steel and/or sheet aluminum.

. . . wherein the housing 1 is configured to be dust-tight.

. . . wherein the housing 1 is reinforced with struts.

. . . wherein the housing 1 is reinforced with struts which enclose a contour of the housing 1.

. . . wherein the heatsink 21 is configured as a profile.

. . . wherein the heatsink 21 forms spaced-apart cooling fins 22.

. . . wherein the heatsink 21 forms spaced-apart cooling fins 22 of a corrugated structure.

. . . wherein the weight of the heatsink 21 is less than one of the values {10 kg, 9 kg, 8 kg, 7 kg, 6 kg, 5 kg}.

It is understood that where a feature mentions “a plurality of” units, components, etc., two or more such units, components, etc. are meant.

In particular, an advantageous embodiment of the mobile rechargeable battery device achieves that it provides a high gross rechargeable battery capacity at a low weight of the device, wherein,
the device provides rotary current for rotary current machines and systems;
its housing can withstand mechanical stress due to impact, as can occur during outdoor use, and thus enables reliable function and safe use of the device both outdoors and indoors;
the electromagnetic compatibility (EMC) of the rechargeable battery device is sufficient to make the device suitable for both indoor and outdoor use;
the device can be transported by hand.

### LEGEND

1 housing
2 baseplate of housing 1
3 hand-drawn trolley
4 lifting handle
5 lifting handle
6 lifting handle with plate 14
7 wheel axle
8 wheel
9 wheel
10 corner region
11 corner region
12 support foot
13 support foot
14 plate for tilting and pulling the rechargeable battery device
15 end face of the rechargeable battery device
16 guide rail
17 switch plate
18 bow handle
19 three-phase alternating current output (rotary current output)
20 cooling surface
21 heatsink
22 cooling fins
23 fan for circulating air cooling
24 accumulator cells
25 power module
26 region with BMS
27 region with safety elements
28 contactor
29 common mode filter
30 eyelets for crane transport
31 rechargeable battery electronics
32 power electronics with rotary current inverter and DC/DC converter
33 rechargeable battery pack
34 electromechanical components, including contactor 29
35 connection cable to rechargeable battery pack 33
36 cable 36, which connects to the common mode filter 29
37 daisy chain
38 bridging cable between the modules 25
39 nut
40 cross strut
41 box frame
42 display
43 on/off switch
44 emergency stop switch
45 single-phase socket
46 CAN output
47 24 V output
48 output for PV charging or DC charging
49 charging cable socket
50 pressure relief or safety valve
51 GPS antenna

1-18. (canceled)

19. A rechargeable battery device for providing three-phase alternating current independently of location, the rechargeable battery device comprising:
a housing with a three-phase alternating current output, wherein one or more rechargeable battery packs, at least one bidirectional three-phase inverter and one or more common mode filters are accommodated in the housing, wherein the housing encloses one or more heatsinks with a heat-dissipating surface for dissipating waste heat to an ambient air, and wherein an energy density of the rechargeable battery device corresponding to a gross capacity of the one or more rechargeable battery packs in relation to a residual weight of the rechargeable battery device is at least 0.1 kilowatt-hour (kWh) per kilogram (kg) (kWh/kg), wherein the residual weight corresponds to a total weight of the rechargeable battery device minus a weight of the one or more rechargeable battery packs.

20. The rechargeable battery device according to claim 19, wherein the gross capacity of the one or more rechargeable battery packs divided by a first weight calculated as the residual weight minus a second weight of the housing without the one or more heatsinks, is at least 0.2 kWh/kg.

21. The rechargeable battery device according to claim 19, wherein the gross capacity of the one or more rechargeable battery packs divided by a weight of the one or more heatsinks is at least 1 kWh/kg.

22. The rechargeable battery device according to claim 19, wherein the gross capacity of the one or more rechargeable battery packs divided by a weight of the one or more common mode filters is at least 3 kWh/kg.

23. The rechargeable battery device according to claim 19, wherein the rechargeable battery device encloses one or more fans for circulating air cooling in the housing with such a maximum power of the one or more fans that the gross capacity of the one or more rechargeable battery packs divided by the maximum power of the one or more fans is at least 1000 hour (h).

24. The rechargeable battery device according to claim 19, wherein, disregarding any switch associated with the housing, any communication interface associated with the housing, or any opening associated with the housing for outputs for any loads, the housing is configured to be closed, except for one or more openings for one or more one-way outlets and except for one or more openings for cooling with ambient air, the one or more openings for cooling being dimensioned such that a solid foreign body of a diameter of at least 1 millimeter (mm) is larger than the one or more openings for cooling and thus cannot pass through the one or more openings for cooling.

25. The rechargeable battery device according to claim 19, wherein the rechargeable battery device includes a bidirectional direct current DC/DC converter, and wherein the bidirectional three-phase inverter and the bidirectional DC/DC converter are configured as a unit.

26. The rechargeable battery device according to claim 19, wherein the three-phase inverter is configured without a transformer.

27. The rechargeable battery device according to claim 19, wherein a nominal voltage of each of the one or more rechargeable battery packs is more than 60 volts (V).

28. The rechargeable battery device according to claim 19, wherein the housing is substantially cuboidal or purely cuboidal, with a maximum length of 900 millimeters (mm), a maximum width of 400 mm and a maximum height of 600 mm.

29. The rechargeable battery device according to claim 19, wherein the housing has at least one handle on which it can be manually moved.

30. The rechargeable battery device according to claim 19, wherein the total weight of the rechargeable battery device is less than 100 kilograms (kg).

31. The rechargeable battery device according to claim 19, wherein the housing has at least one handle, and wherein the rechargeable battery device is configured as a hand-drawn trolley with at least one wheel on the housing for manually rolling the rechargeable battery device using the at least one handle.

32. The rechargeable battery device according to claim 31, wherein the hand-drawn trolley has support feet on a side of the housing opposite one or more individual wheels so that the hand-drawn trolley can be tilted about an axle of the one or more individual wheels and can be set down on a ground level in a horizontal position of the housing using the support feet, and wherein the hand-drawn trolley has a lifting handle for tilting and rolling the hand-drawn trolley.

33. The rechargeable battery device according to claim 31, wherein the housing includes a baseplate, wherein the hand-drawn trolley has a lifting handle which can be extended along the baseplate of the housing, wherein the lifting handle comprises a plate and an end handle device attached to the plate, and wherein the plate can be extended in a normal direction relative to an end face of the hand-drawn trolley or the hand-drawn trolley has a bow handle which can be folded out in the normal direction relative to the end face of the hand-drawn trolley.

34. The rechargeable battery device according to claim 31, wherein the hand-drawn trolley has a lifting handle at each of two opposite upper corner regions of the housing, and wherein the lifting handle is configured to fold-out or has a fixed arrangement.

35. The rechargeable battery device according to claim 19, wherein the housing includes a baseplate, and wherein the baseplate is vertically spaced from the rechargeable battery device by at least 10 centimeters (cm) when the rechargeable battery device is placed on a ground level.

36. The rechargeable battery device according to claim 19, wherein the housing comprises at least two struts, each strut of the at least two struts extending along a longitudinal edge of a top panel of the housing.
